(19) United States
(12) Patent Application Publication
(10) Pub. No.: US 2012/0235206 A1
(43) Pub. Date: Sep. 20, 2012

(54) LIGHTING DEVICE AND METHOD FOR CONTACTING A LIGHTING DEVICE

(75) Inventors: Andreas Kampfrath, Niederstrotzingen (DE); Steffen Strauss, Regensburg (DE)

(73) Assignee: OSRAM AG, Muenchen (DE)

(21) Appl. No.: 13/512,888

(22) PCT Filed: Nov. 17, 2010
(86) PCT No.: PCT/EP10/67626

§ 371 Date: May 31, 2012

(30) Foreign Application Priority Data
Dec. 3, 2009 (DE) 10 2009 047 438.2

(51) Int. Cl. H01L 33/62

(52) U.S. Cl. 257/99; 438/26; 257/E33.066

(57) ABSTRACT

A lighting device may include a printed circuit board, wherein the printed circuit board has wiring on at least one of the front side and the back side thereof, the respective wiring is covered by at least one potting layer, the lighting device furthermore has at least one electrically conductive punched bushing and the punched bushing extends through a potting layer at least to the wiring and contacts the wiring.

The invention relates to a lighting device, including a printed circuit board, wherein the printed circuit board has wiring on the front side and/or on the back side thereof and the respective wiring is covered by a potting layer. The invention furthermore relates to a method for contacting such a lighting device.

LED light strips are known for example from the LINEARLight range from the Osram company which have a strip-shaped printed circuit board, wherein the printed circuit board is equipped on one side with light emitting diodes. Associated wiring, including electrical contacts, is accordingly situated on the side equipped with the light emitting diodes, which is typically referred to as the front side. The back side is intended for fastening the LED light strip and is provided with a double-sided adhesive tape for this purpose.

LED light strips embedded in a potting compound have hitherto been available for effecting an upgrade in respect of an IP protection class. These potted LED light strips are available as prefabricated and preassembled LED light strips having fixed lengths, wherein electrical contacting is provided by way of similarly embedded plug connectors or cables. For installation on the part of the customer, plug connector sets are available wherein the customer removes the potting material manually, solders the cables or the plug connector on discretely, and must restore the potting integrity of the product using a portion of silicone or the like also supplied. In this situation the customer's right to claim under the manufacturer's warranty is invalidated and the IP classification is no longer guaranteed by the manufacturer or supplier.

The object of the present invention is to provide a simple facility for contacting potted contacts of a lighting device, wherein an IP protection class can be maintained.

This object is achieved in accordance with the features of the independent claims. Preferred embodiments are set down in particular in the dependent claims.

The object is achieved by a lighting device, including a printed circuit board, wherein the printed circuit board has wiring on the front side and/or on the back side thereof, wherein the respective wiring is covered by at least one potting layer.

The wiring may in particular include electrical contacts, in particular contact areas or contact pads.

The lighting device furthermore has at least one electrically conductive punched bushing, wherein the punched bushing extends through the potting layer at least to the wiring and consequently electrically contacts the wiring. The punched bushing may in particular be a piercing die bush which cuts into the potting material. For this purpose, the piercing die bush may have a cutting edge.

The punched bushing is in general designed to be tubular in form may can be pressed with one end, which is referred to in the following as the front end, into the potting layer, wherein the end cuts through the potting layer to the point where it meets the printed circuit board. The through-cut is made without exposing the board, which means that the at least partially potted printed circuit board can be contacted in a simple manner, precisely and without compromising the protective function of the potting layer. It is a simple matter to connect electrical lines providing an external electrical connection for the lighting device to the punched bushing. In this situation it is possible to route the electrical line(s) upwards away from the lighting device. It is a further advantage that the punched bushing can be incorporated into the potting layer at any desired position and is not restricted for example to longitudinal-side ends. This may also offer greater design flexibility with regard to the wiring of the printed circuit board. A simple preassembly of divisible light strips on the part of the customer is also enabled in this manner without the divided light strips losing their IP protection class. In addition, a dense arrangement of a plurality of punched bushings and thus dense contacting of the printed circuit board are possible. As a result of the fact that it is possible to dispense with equipping the printed circuit board with electrical connection elements during manufacture, the manufacturing process furthermore becomes simpler and more cost-effective. In particular for the case where the printed circuit board is flexible, in particular flexible and strip-shaped, the simple production of a potted printed circuit board is also possible because this can be processed virtually continuously, for example by means of a reel-to-reel manufacturing process. A flexible potted printed circuit board does not lose any significant degree of its flexibility as a result of using the punched bushing. In addition, the contacting by means of the at least one punched bushing can be combined with other types of electrical connection (for example using plug connectors).

The punched bushing can extend to the wiring or through the wiring, and in particular to a back side of the lighting device. If the punched bushing extends to the back side of the lighting device, it may also be contacted there and moreover exhibits a greater stability against a mechanical load. If the punched bushing extends to the back side of the lighting device, it can also be riveted like a punch rivet, which means that the front end and the rear end have a lateral rim which prevents the punched bushing or the punch rivet from becoming loose and thereby enables mechanically particularly stable contacting. The punched bushing may in general also be regarded and referred to as a hollow punch rivet.

The front end of the punched bushing may be designed as a sharp edge or cutting contact for cutting through the potting layer.

The cylindrical piece of potting compound situated in the punched bushing may be loosened and removed from the printed circuit board. The inside space which is then exposed may be used for electrical contacting as a bushing which may be contacted by a plug connector and/or, in the case of a punched bushing passing through the lighting device, as a cable lead-through.

It is an embodiment that the printed circuit board has wiring only on the front side thereof (on one side, in other words), which is covered by the potting layer. The printed circuit board may furthermore also have wiring on the back side thereof, which however is not covered by a potting layer. The lighting device moreover has at least one punched bushing counterpart, referred to in the following simply as punching pin, which extends through the printed circuit board (including the wiring thereof) from the other side of the lighting device with respect to the punched bushing and is engaged with the punched bushing.

Contacting is made more reliable by means of the punching pin because this prevents the punched bushing from becoming detached, in particular when subjected to a shear load and a tensile load. It is also possible by means of the punching pin to bend up the wiring, in particular the contact area, which thus presses more firmly against the punched bushing and/or the punching pin and consequently enables more solid contacting.

It is another embodiment that the punched bushing and the punching pin are engaged in nonpositive fashion. A particularly solid connection between the punched bushing and the punching pin is achieved as a result. Nonpositive engagement may for example be achieved in that the punching pin is wider than an inside diameter of the punched bushing and tapers at its tip engaging in the punched bushing, e.g. is designed to be conical in shape. This means that the punching pin may be pressed into the punched bushing and held there by means of friction locking.

It is furthermore an embodiment that the punching pin is tubular in form. It is thereby possible to achieve a through-hole through the lighting device, which is suitable for example for a cable lead-through or for contacting by means of a plug connector.

It is a further embodiment that the at least one punched bushing contacts a contact area of the wiring in each case. As a result of the (flat) contact area, it is possible to provide a sufficiently large and well defined contact point for the printed circuit board.

It is a further embodiment that on its front side the lighting device has at least one light source, in particular a light emitting diode. The back side of the board can be provided for the fastening thereof, for example by means of a double-sided adhesive tape.

It is also an embodiment that the punched bushing and/or the punching pin has a rim running laterally on the rear end thereof.

A stop is formed by the respective rim for the punched bushing and/or the punching pin, which stop prevents it from being fully inserted into the lighting device.

It is a development that the printed circuit board is designed to be strip-shaped. The lighting device can then in particular constitute an LED light strip.

It is another embodiment that an outside of the punched bushing is equipped with at least one barbed hook which has a backward pointing barb. By this means the punched bushing may be introduced simply into the potting layer while the at least one barbed hook fixes the punched bushing in the potting layer and thereby prevents it from being pulled out.

The potting layer may have one or more potting materials or potting compounds, in particular a plurality of sublayers of different adjacent potting compounds, for example an opaque potting compound and a translucent potting compound.

The potting layer may in particular have silicone as its base material.

The object is also achieved by a method for contacting a lighting device including a printed circuit board, wherein the printed circuit board has wiring on the front side and/or on the back side thereof and the respective wiring is covered by a potting layer, wherein the method has at least the following step: Pressing in an electrically conductive punched bushing through the potting layer to the wiring such that the punched bushing contacts the wiring, in particular also makes electrical contact therewith.

It is a development that the method additionally has at least the following step: Positioning a punching pin on the back side of the printed circuit board opposite the punched bushing and subsequently pushing the punching pin through the printed circuit board and the wiring until the punching pin is engaged with the punched bushing.

The steps of pressing in the electrically conductive punched bushing and pushing the punching pin through may take place successively or simultaneously.

The pressing or punching may be performed by means of a suitable tool, for example a punching tool, riveting tool or setting tool. The tool may be a simple pair of pliers.

In the following figures, the invention will be described schematically in detail with reference to an exemplary embodiment. In this situation, the same elements or elements having the same function can be provided with the same reference characters for the sake of clarity.

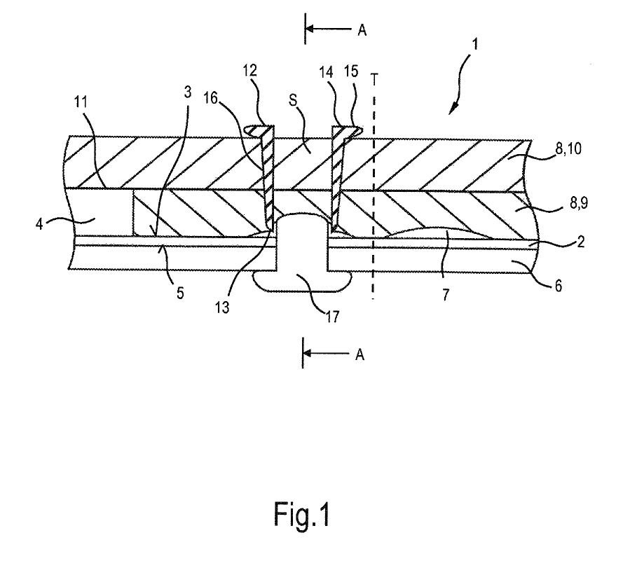

FIG. 1 shows a sectional side view of part of a lighting device according to the invention; and

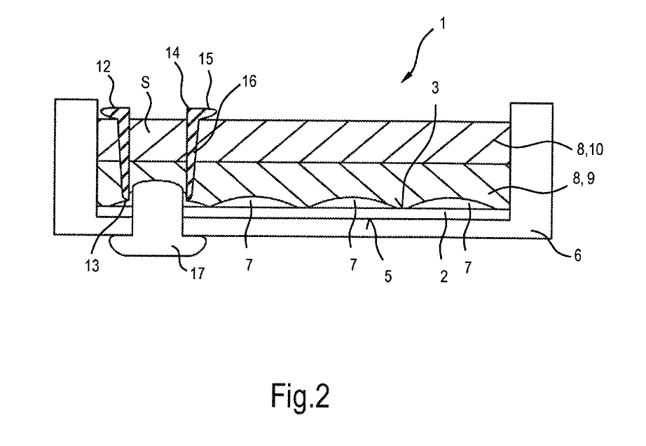

FIG. 2 shows a sectional front view of the lighting device according to the invention.

FIG. 1 shows a sectional side view of part of a lighting device 1 according to the invention. FIG. 2 shows a sectional front view of the lighting device 1.

With reference to FIG. 1 and FIG. 2, the lighting device 1 has a strip-shaped flexible printed circuit board 2, the upper side or front side 3 of which is equipped with light emitting diodes 4 arranged in series. A back side 5 of the printed circuit board 2 is fastened on a floor of an elongated profile 6 having a U-shaped cross-section (see FIG. 2). The profile 6 may have silicone as its base material in order to allow the lighting device 1 to at least partially retain its flexibility. The profile 6 may in particular consist of an opaque material. The light emitting diodes 4 emit upwards from the open side of the profile 6, wherein the profile 6 projects upwards above the equipped printed circuit board 2, 4.

On the front side 3 of the printed circuit board 2 is situated wiring for the elements fastened thereto (light emitting diodes 4 and where applicable further electronic components such as a driver module, capacitors and/or resistances), only electrical contacts 7 of which are shown. The electrical contacts 7 can be situated for example on both sides of a division point T, at which the lighting device 1 or the potted printed circuit board 2, 4, 8 can be divided and can thus be prefabricated to length.

The equipped printed circuit board 2, 4 is embedded inside the profile 6 by means of a potting layer 8 which consists of two potting sublayers 9, 10 lying on top of one another. A lower first potting sublayer 9, which will have been applied first, covers the printed circuit board 2 up to an upper side 11 of the light emitting diodes 4. The upper side 11 is not covered by the first potting sublayer 9 and includes the light emitting region of the light emitting diode 4. The profile 6 and the first potting sublayer 9 protect the printed circuit board 2, 4 up to the respective upper side 11 of the light emitting diode(s) 4, for example in order to meet the requirements of an IP class.

The first potting sublayer 9 is opaque and is designed to give a uniform color appearance in the same color as the profile 6. This can be achieved for example by means of a color additive (colored filler particles etc.) added to an otherwise non-colored base material. Apart from the respective upper side 11 of the light emitting diode(s) 4, the equipped printed circuit board 2, 4 thus remains hidden from view. The first potting sublayer 9 may have silicone as its base material in order to provide good processability with a high level of protection, good resistance to aging, and flexibility. Also, there is no mismatch with the material used for the profile 6 and a very good connection is thereby achieved.

In order to also protect the upper side 11 of the light emitting diode(s) 4 a second potting sublayer 10 which is transparent or highly translucent, having a high transmissivity, for example made of silicone with no color additive, is applied on the first potting sublayer 9. The equipped printed circuit board 2, 4 is completely embedded by the second potting sublayer 10 and thus protected. The second potting sublayer 10 advantageously consists of the same base material as the first potting sublayer 9.

A punched bushing 12 is used here to provide electrical contacting of the printed circuit board 2, in particular after a division along the division point T. The punched bushing 12 consists of an electrically conductive material, for example metal. The punched bushing 12 exhibits a tubular or sleeve-like basic form which has a cutting edge on the front rim 13 thereof. On its rear rim 14 the punched bushing 12 has a collar 15 running laterally. The punched bushing 12 has been lowered from above with the front rim 13 leading vertically onto one of the electrical contacts 7 and in doing so has cut through the potting layer 8. The front rim 13 is now in mechanical and electrical contact with the associated contact 7 and has thus separated a cylindrical piece S from the potting layer 8, which here is still situated in the punched bushing 12. The potting layer 8 is slightly compressed locally by the punched bushing 12 and consequently presses gently against the punched bushing 12. A gap between the potting layer 8 and the punched bushing 12, through which moisture or dust could otherwise penetrate, is thus avoided. An outside 16 of the punched bushing 12 can be provided with barbed hooks (not illustrated) in order to prevent the punched bushing 12 coming loose from the potting layer 8.

The punched bushing 12 can be connected to an electrical line to provide the electrical connection with the printed circuit board 2 and thus to operate the lighting device 1. This can take place using any suitable method, for example by means of soldering. Alternatively, after removal of the cylindrical piece S a plug connector can be introduced in nonpositive fashion into the punched bushing 12. As a general rule the (cylindrical or differently shaped) piece S can remain in the punched bushing 12 or similar, which means that a protective function is reliably maintained. If the piece S is removed, the protective function and thus an IP protection class may possibly be compromised. On the other hand, the hole resulting from the removal of the piece S (blind hole or through-hole) can be quickly and neatly sealed again on the part of the customer, for example by means of a silicone adhesive.

In principle, contacting of a contact 7 may take place by means of the punched bushing 12 alone. In order to attain a particularly stable attachment of the punched bushing 12 on the potted printed circuit board 2, 4, 8, a punched bushing counter-element here in the form of a punching pin 17 is pushed or pressed into the lighting device 1 from an underside of the lighting device 1 at a position opposite the punched bushing 12. For this purpose, the punching pin 17 can in particular be positioned and driven in at the same time as or after introduction of the punched bushing 12. The punching pin 17 penetrates the profile 6, the printed circuit board 2 and the contact 7 and travels into the punched bushing 12 at the front end 13. There it is engaged in nonpositive fashion with the punched bushing 12. In this situation, the punching pin 17 pushes the cylindrical piece S upwards such that the latter can be easily removed. The punching pin 17 can, as shown, be configured as a full element.

Alternatively, the punching pin 17 may be designed as a ring-shaped or sleeve-like hollow part, such that a continuous through-hole from the upper side of the lighting device to the underside of the lighting device through the punched bushing 12 and the punching pin 17 results. This through-hole can for example be used for a cable lead-through or as a continuous bushing for receiving a plug connector. The through-hole can be sealed again after inserting the plug connector or at least one cable (which means for example that the at least one cable is also sealed at the same time) in order to be able to reliably maintain a protective function. This also strengthens the fastening in the through-hole.

In order to provide a secure introduction and nonpositive connection, the punching pin can be designed to be tapered, for example conical, at least at the tip thereof.

The punched bushing 12 and the punching pin 17 can be assembled using a common tool.

The present invention is naturally not restricted to the exemplary embodiment shown.

### LIST OF REFERENCE CHARACTERS

1 Lighting device
2 Printed circuit board
3 Front side of printed circuit board
4 Light emitting diode
5 Back side
6 Profile
7 Electrical contact
8 Potting layer
9 Potting sublayer
10 Potting sublayer
11 Upper side
12 Punched bushing
13 Front rim
14 Rear rim
15 Collar
16 Outside
17 Punching pin
T Division point
S Cylindrical piece

1. A lighting device, comprising:
a printed circuit board, wherein
the printed circuit board has wiring on at least one of the front side and the back side thereof,
the respective wiring is covered by at least one potting layer,
the lighting device furthermore has at least one electrically conductive punched bushing and
the punched bushing extends through a potting layer at least to the wiring and contacts the wiring.

2. The lighting device as claimed in claim 1,
wherein the printed circuit board has wiring only on the front side thereof, which is covered by the potting layer and
the lighting device furthermore has at least one punching pin, which extends through the printed circuit board from the other side of the lighting device with respect to the punched bushing and is engaged with the punched bushing.

3. The lighting device as claimed in claim 2, wherein the punched bushing and the punching pin are engaged in nonpositive fashion.

4. The lighting device as claimed in claim 2,
wherein the punching pin is tubular in shape.

5. The lighting device as claimed in claim 1,
wherein the at least one punched bushing contacts a contact area of the wiring in each case.

6. The lighting device as claimed in claim 1,
wherein the lighting device has at least at least one light source on the front side thereof.

7. The lighting device as claimed in claim 1,
wherein at least one of the punched bushing and the punching pin has a rim running laterally on the rear end thereof.

8. The lighting device as claimed in claim 1,
wherein an outside of the punched bushing is equipped with at least one barbed hook which has a backward pointing barb.

9. A method for contacting a lighting device comprising a printed circuit board, wherein the printed circuit board has wiring on at least one of the front side and the back side thereof and the respective wiring is covered by a potting layer, the method comprising:
pressing in an electrically conductive punched bushing through the potting layer to the wiring such that the punched bushing contacts the wiring.

10. The method as claimed in claim 9, further comprising:
positioning a punching pin on the back side of the printed circuit board opposite the punched bushing and subsequently pushing the punching pin through the printed circuit board and the wiring until the punching pin is engaged with the punched bushing.

11. The lighting device as claimed in claim 6,
wherein the at least at least one light source comprises a light emitting diode.
